(19) United States
(12) Patent Application Publication
(10) Pub. No.: US 2026/0157071 A1
(43) Pub. Date: Jun. 4, 2026

(54) DISPLAY PANEL AND DISPLAY DEVICE

(71) Applicants: Mianyang HKC Optoelectronics Technology Co., Ltd., Mianyang (CN); HKC Corporation Limited, Shenzhen (CN)

(72) Inventors: QIN LIANG, Mianyang (CN); Zhisheng Xie, Mianyang (CN); Yangling Tang, Mianyang (CN); Haijiang Yuan, Mianyang (CN)

(21) Appl. No.: 19/387,646

(22) Filed: Nov. 13, 2025

(30) Foreign Application Priority Data
Nov. 29, 2024 (CN) 202411735637.5

(51) Int. Cl. H10K 59/38; H10K 59/122; H10K 59/80

(52) U.S. Cl. CPC H10K 59/38; H10K 59/122; H10K 59/873; H10K 59/8792

(57) ABSTRACT

Disclosed are a display panel and a display device. The display panel includes a substrate, a pixel driving layer, a pixel defining layer, a plurality of light-emitting elements, an encapsulation layer and a color-filtering layer. The pixel defining layer is disposed on the pixel driving layer and located in a plurality of non-opening areas. The plurality of light-emitting elements are arranged in an array on the pixel driving layer and respectively located in the plurality of opening areas. The encapsulation layer includes an organic encapsulation layer; the organic encapsulation layer is provided with a first groove corresponding to each of the plurality of non-opening areas. The color-filtering layer includes a plurality of light-shielding portions and a plurality of color-filtering portions, the plurality of color-filtering portions are respectively arranged in the plurality of opening areas, and the plurality of light-shielding portions are respectively arranged in a plurality of first grooves.

### CROSS-REFERENCE TO RELATED APPLICATIONS

The present application claims the priority and benefit of Chinese patent application number 2024117356375, titled "Display Panel and Display Device" and filed on November 29, 2024 with China National Intellectual Property Administration, the entire contents of which are incorporated herein by reference.

### TECHNICAL FIELD

The present application relates to the technical field of display, and more particularly relates to a display panel and a display device.

### BACKGROUND

The description provided in this section is intended for the mere purpose of providing background information related to the present application but doesn’t necessarily constitute prior art.

With the continuous development of Organic Light-Emitting Diode (hereinafter referred as OLED) display technology, OLED display technology is increasingly used in displays such as smartphones, tablets, computers, and televisions. OLED displays have the advantages of being thin and light, high contrast, fast response, wide viewing angle, high brightness, and full color. In order to reduce the reflectivity of external light in OLED displays, the current mainstream solution is to attach a circular polarizer to the light-emitting surface of the OLED display. However, this solution reduces the light-emitting effect due to the large light loss of the circular polarizer. Another solution is to set a color-filtering layer on the light-emitting surface of the OLED display to improve the light-emitting efficiency. A black matrix (hereinafter referred as BM) can be set to reduce the effect of ambient light reflection in the OLED display, and the thickness of the entire display panel may also be reduced.

However, in the process of preparing color-filtering layer on the display panel, the overlap position of the formed black matrix and later-formed color-filtering portion tends to be stacked to form a "ox-horn" defect, causing problems such as uneven display, since a color-filtering portion needs to be made of color-filtering material after the black matrix process.

### SUMMARY

The purpose of the present application is to provide a display panel and a display device. The present application employs an organic encapsulation layer to form a first groove to accommodate a light-shielding portion, such that the film layer below the color-filtering portion exhibit improved flatness when a color-filtering portion is formed. The overlapping portion of the color-filtering portion and the light-shielding portion do not exhibit "ox-horn" defects, thereby improving the color purity and uniformity of the color-filtering portion at various positions within a same opening area.

The present application discloses a display panel, including a plurality of opening areas and a plurality of non-opening areas. The display panel includes a substrate, a pixel driving layer, a pixel defining layer, a plurality of light-emitting elements, an encapsulation layer and a color-filtering layer. The pixel driving layer is disposed on the substrate. The pixel defining layer is disposed on the pixel driving layer and located in a plurality of non-opening areas. The plurality of light-emitting elements are arranged in an array on the pixel driving layer and respectively located in the plurality of opening areas. The encapsulation layer is disposed on the plurality of light-emitting elements, and the encapsulation layer includes an organic encapsulation layer, the organic encapsulation layer is provided with a first groove corresponding to each of the plurality of non-opening areas. The color-filtering layer is disposed on the encapsulation layer, and the color-filtering layer includes a plurality of light-shielding portions and a plurality of color-filtering portions, the plurality of color-filtering portions are respectively arranged in the plurality of opening areas, and the plurality of light-shielding portions are respectively arranged in a plurality of first grooves.

In some embodiments, the plurality of color-filtering portions includes a plurality of first color-filtering portions and a plurality of second color-filtering portions; a color of each of the plurality of first color-filtering portions is different from that of each of the plurality of second color-filtering portions; and in each of the plurality of non-opening areas, each of the plurality of first color-filtering portions is provided with a first color extension portion, each of the plurality of second color-filtering portions is provided with a second color extension portion, and the first color extension portion and the second color extension portion are stacked to form the light-shielding portion.

In some embodiments, each of the plurality of first color-filtering portions is a red color-filtering portion, and each first color extension portion is a red extension portion; each of the plurality of second color-filtering portions is a blue color-filtering portion, and each second color extension portion is a blue extension portion; the red extension portion is disposed below the blue extension portion within each of the plurality of non-opening areas.

In some embodiments, in each of the plurality of non-opening areas, in an orthographic projection on the substrate, an overlapping area of the red extension portion and the blue extension portion is greater than or equal to an area of the first grooves.

In some embodiments, a surface of the blue extension portion away from the substrate is in the same plane as surfaces of the blue color-filtering portion and the red color-filtering portion away from the substrate.

In some embodiments, the encapsulation layer further includes a first inorganic encapsulation layer, disposed on the organic encapsulation layer, and the first inorganic encapsulation layer covers the plurality of first grooves to form a plurality of second grooves respectively; within each of the plurality of non-opening areas, the red extension portion and the blue extension portion are disposed in the plurality of second grooves, and a depth of each of the plurality of second grooves is equal to any one of a thickness of the blue extension portion and a thickness of the red extension portion.

In some embodiments, the display panel further includes a plurality of overhang structures, disposed on the pixel defining layer; each of the plurality of overhang structures is configured to separate two adjacent light-emitting elements respectively.

In some embodiments, the plurality of color-filtering portions includes a plurality of red color-filtering portions, a plurality of blue color-filtering portions and a plurality of green color-filtering portions; each of the plurality of red color-filtering portions is provided with a red extension portion, each of the plurality of green color-filtering portions is provided with a green extension portion, each of the plurality of blue color-filtering portions is provided with a blue extension portion; and any two of the red extension portion, the green extension portion and the blue extension portion are stacked to form the light-shielding portion in each of the plurality of non-opening areas.

In some embodiments, each of the plurality of light-shielding portions is formed of a black light-shielding material; at least one of the color-filtering portions is disposed to covers the light-shielding portion in each of the plurality of non-opening areas, and the light-shielding portion partially overlaps the color-filtering portion in the orthographic projection on the substrate.

In some embodiments, the encapsulation layer further includes a first inorganic encapsulation layer, disposed on the organic encapsulation layer, and the first inorganic encapsulation layer covers the plurality of first grooves to form a plurality of second grooves respectively; a thickness of each of the plurality of light-shielding portions is less than or equal to a depth of each of the plurality of second grooves.

In some embodiments, the light-shielding portion is covered with at least one color-filtering portion in each of the plurality of non-opening areas.

In some embodiments, a side wall of each first groove has a multi-stepped stair-like surface; and a side wall of each of the plurality of second grooves has a multi-stepped stair-like surface.

The present application further discloses a display device, including a display panel and a driving circuit configured to drive the display panel to display. The display panel includes a substrate, a pixel driving layer, a pixel defining layer, a plurality of light-emitting elements, an encapsulation layer and a color-filtering layer. The pixel driving layer is disposed on the substrate. The pixel defining layer is disposed on the pixel driving layer and located in a plurality of non-opening areas. The plurality of light-emitting elements are arranged in an array on the pixel driving layer and respectively located in the plurality of opening areas. The encapsulation layer is disposed on the plurality of light-emitting elements, and the encapsulation layer includes an organic encapsulation layer, the organic encapsulation layer is provided with a first groove corresponding to each of the plurality of non-opening areas. The color-filtering layer is disposed on the encapsulation layer, and the color-filtering layer includes a plurality of light-shielding portions and a plurality of color-filtering portions, the plurality of color-filtering portions are respectively arranged in the plurality of opening areas, and the plurality of light-shielding portions are respectively arranged in a plurality of first grooves.

In the present application, the plurality of first grooves are disposed on the organic encapsulation layer, and the plurality of first grooves are arranged corresponding to the positions of the plurality of non-opening areas respectively. The plurality of light-shielding portions are respectively provided in the plurality of first grooves, so as to realize the setting of sinking the plurality of light-shielding portions. The film layer below the plurality of color-filtering portions is relatively flat when the plurality of color-filtering portions are formed, and the overlapping portions of color-filtering portion and light-shielding portions respectively do not exhibit "ox-horn" defects, thereby reducing the differences in spectrum and brightness at different positions of the plurality of color-filtering portions due to the different thicknesses at the middle and edge positions of the color-filtering portion, improving the color purity and uniformity of each position of the color-filtering portion in the same opening area, improving the display effect under a wide viewing angle, and reduing the color separation phenomenon caused by the reflection of ambient light by the display panel. Moreover, the present application utilizes that the organic encapsulation layer has a certain thickness, and the plurality of first groove may be formed to accommodate the plurality of light-shielding portions. There is no need to set an additional film layer to form the plurality of first groove, which reduces the overall thickness of the film layer of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a top view schematic diagram of a display panel of a first embodiment of the present application.

FIG. 2 is a schematic cross-sectional view of FIG. 1 along the cutting line A-A.

FIG. 3 is a schematic diagram of another display panel of a first embodiment of the present application.

FIG. 4 is a schematic diagram of a display panel of a second embodiment of the present application.

FIG. 5 is a schematic diagram of the second display panel of a second embodiment of the present application.

FIG. 6 is a schematic diagram of another display panel of a second embodiment of the present application.

FIG. 7 is a schematic diagram of a display device according to the present application.

Reference Numerals: 100, display panel; 101, opening area; 102, non-opening area; 110, substrate; 111, pixel driving layer; 112, pixel defining layer; 113, light-emitting element; 120, encapsulation layer; 121, first inorganic encapsulation layer; 122, organic encapsulation layer;123, second inorganic encapsulation layer; 124, first groove; 125, second groove; 130, color-filtering layer; 140, color-filtering portion; R, red color-filtering portion; G, green color-filtering portion; B, blue color-filtering portion; RE, red extension portion; GE, green extension portion; BE, blue extension portion; 150, light-shielding portion; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application may be implemented in many alternative forms and should not be construed as being limited to only these embodiments described herein.

As used herein, terms "first", "second", or the like are merely used for illustrative purposes, and shall not be construed as indicating relative importance or implicitly indicating the number of technical features specified. Thus, unless otherwise specified, the features defined by "first" and "second" may explicitly or implicitly include one or more of such features. Terms "multiple", "a plurality of", and the like mean two or more. In addition, terms "up", "down", "left", "right", "vertical", and "horizontal", or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application may be understood depending on specific contexts.

The present application is described in detail below with reference to the accompanying drawings and some optional embodiments.

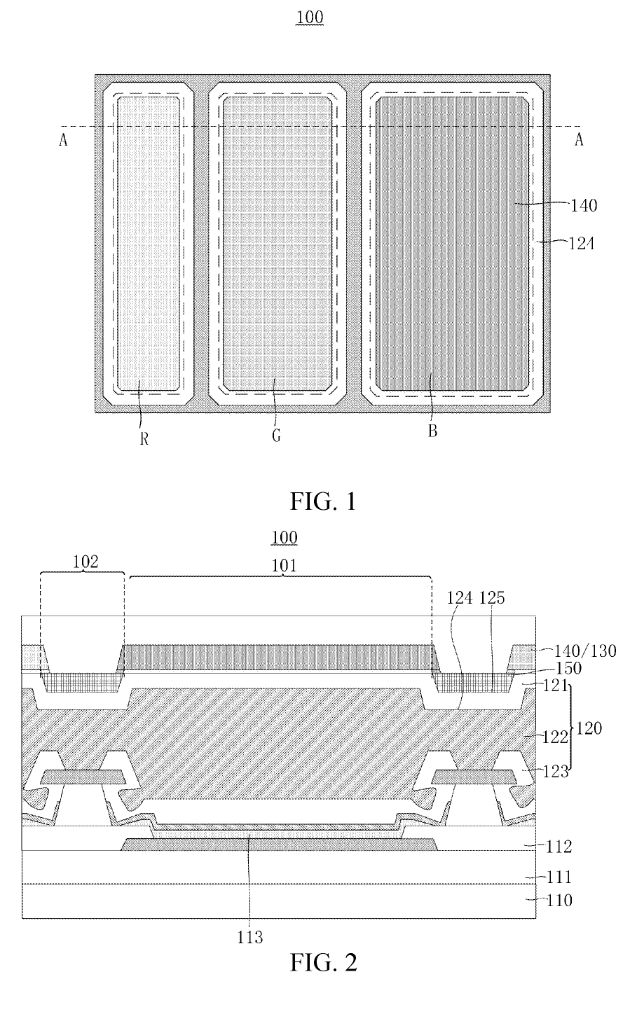

FIG. 1 is a schematic top view of a display panel of a first embodiment of the present application. FIG. 2 is a schematic cross-sectional view of FIG. 1 along the cutting line A-A. As shown in FIGS. 1 and 2, the present application discloses a display panel. The display panel 100 includes a plurality of opening areas 101 and a plurality of non-opening areas 102. The display panel 100 further includes a substrate 110, a pixel driving layer 111, a pixel defining layer 112, a plurality of light-emitting elements 113, an encapsulation layer 120 and a color-filtering layer 130. The pixel driving layer 111 is disposed on the substrate 110. The pixel defining layer 112 is disposed on the pixel driving layer 111 and located in the plurality of non-opening areas 102. The plurality of light-emitting elements 113 are arranged in an array on the pixel driving layer 111 and respectively located in the plurality of opening areas 101. The encapsulation layer 120 is disposed on the plurality of light-emitting elements 113, and the encapsulation layer 120 includes an organic encapsulation layer 122, the organic encapsulation layer 122 is provided with a first groove 124 corresponding to each of the plurality of non-opening areas 102. The color-filtering layer 130 is disposed on the encapsulation layer 120, and the color-filtering layer 130 includes a plurality of light-shielding portions 150 and a plurality of color-filtering portions 140, the plurality of color-filtering portions 140 are respectively arranged in the plurality of opening areas 101, and the plurality of light-shielding portions 150 are respectively arranged in a plurality of first grooves 124.

In the present application, the plurality of first grooves 124 are disposed on the organic encapsulation layer 122, and the plurality of first grooves124 are arranged corresponding to the positions of the plurality of non-opening areas 102 respectively. The plurality of light-shielding portions 150 are respectively provided in the plurality of first grooves 124, so as to realize the setting of sinking the plurality of light-shielding portions 150. The film layer below the plurality of color-filtering portions 140 is relatively flat when the color-filtering layer 130 is formed, and the overlapping portions of the plurality of color-filtering portions 140 and the plurality of light-shielding portions 150 respectively do not exhibit "ox-horn" defects, thereby reducing the problem of differences in spectrum and brightness at different positions of the plurality of color-filtering portions 140 caused by the different thicknesses at the middle and edge positions of the color-filtering portion 140, improving the color purity and uniformity of each position of the color-filtering portion 140 in the same opening area 101, improving the display effect under a wide viewing angle is improved, and reducing the color separation phenomenon caused by the reflection of ambient light by the display panel 100. Moreover, the present application utilizes that the organic encapsulation layer 122 has a certain thickness, and the plurality of first grooves 124 may be formed to accommodate the plurality of light-shielding portions 150. There is no need to set an additional film layer to form the plurality of first grooves 124, which reduces the overall thickness of the film layer of the display panel 100.

Specifically, the display panel 100 of the present application is an organic light-emitting display panel provided with a color-filtering but not a polarizer, also known as a Color Film on Encapsulation (hereinafter referred to as COE) display panel. In the process of forming the color-filtering layer 130, the display panel 100 needs to first make a light-shielding portion 150 (e.g., a black matrix) before forming the color-filtering portion 140, and in this process, due to a certain thickness of the black matrix, the overlapping position of the color-filtering portion 140 and the black matrix is prone to form an "ox-horn" defect. That is, the film layer of the color-filtering portion 140 is uneven, especially at the edge position of the black matrix, the upper surface of the color-filtering portion 140 has obvious bulges, resulting in uneven film layer on the upper surface of the color-filtering portion 140. The present application realizes the downward movement of the light-shielding portion 150 by setting the plurality of first grooves 124 on the organic encapsulation layer 122. In the process of forming the plurality of color-filtering portions 140 after forming the plurality of light-shielding portions 150, a relatively flat surface is formed below the plurality of color-filtering portions 140, which is not affected by the black matrix. That is, no "ox-horn" defect of stacking with the black matrix is formed.

Specifically, the pixel driving layer 111 is provided with a pixel driving circuit for driving the plurality of light-emitting elements 113. The pixel driving circuit includes such as a thin film transistor, a data driving line, and a scanning line. The above-mentioned thin film transistor, data driving line, and scanning line are formed by multiple metal film layers and insulating film layers. A flat layer is generally also provided on the pixel driving layer 111, and the subsequent light-emitting element 113 and the pixel defining layer 112 are respectively provided on the flat layer.

Specifically, the pixel defining layer 112 is provided with a plurality of openings, the position of the openings is also referred to as the opening area 101, and the position where the pixel defining layer 112 is provided is also referred to as the non-opening area 102. The plurality of light-emitting elements 113 are respectively provided in the plurality of opening areas 101, and two adjacent light-emitting elements 113 are separated by the pixel defining layer 112.

Specifically, the encapsulation layer 120 covers the plurality of light-emitting elements 113 and the pixel defining layer 112, and the encapsulation layer 120 is configured to encapsulate the plurality of light-emitting elements 113 to prevent external water vapor from entering the light-emitting elements 113. The encapsulation layer 120 in the present embodiment adopts thin film encapsulation technology, that is, a stack formed by multiple layers of inorganic materials and organic materials. The organic encapsulation layer 122 is formed by organic materials. The encapsulation layer 120 also includes a first inorganic layer 121 disposed on the organic encapsulation layer 122, and the first inorganic layer 121 covers the plurality of the first grooves 124 to form a plurality of second grooves 125, and the plurality of color-filtering portion 140 are respectively arranged in the plurality of second grooves 125. The first inorganic layer 121 is formed by an inorganic material, and a thickness of the first inorganic layer 121 is generally much less than a thickness of the organic encapsulation layer 122.

In the present embodiment, by providing the plurality of first grooves 124 on the organic encapsulation layer 122, the plurality of second grooves 125 are formed at positions corresponding to the plurality of first grooves 124 when forming the first inorganic layer 121, so that the plurality of color-filtering portions 140 are respectively provided in the plurality of second grooves 125. Relatively speaking, the organic encapsulation layer 122 has a relatively thick film, allowing formation of the first groove 124 with greater depth thereon to accommodate the color-filtering portion 140.

In the present embodiment, the encapsulation layer 120 may be encapsulated by stacking three layers of films, and the encapsulation layer 120 includes the first inorganic encapsulation layer 121, the organic encapsulation layer 122, and a second inorganic encapsulation layer 123. The second inorganic layer 123 covers the plurality of light-emitting elements 113 and is located under the organic encapsulation layer 122. The organic encapsulation layer 122 is disposed on the second inorganic layer 123, and the first inorganic layer 121 is disposed on the organic encapsulation layer 122. The color-filtering layer 130 is directly in contact with the first inorganic layer 121. It is worth mentioning that, in the present embodiment, the plurality of first grooves 124 are formed on the organic encapsulation layer 122, and the organic encapsulation layer 122 has a relatively thick film, rendering little effect to the organic encapsulation layer 122.

Specifically, the plurality of light-shielding portions 150 in the present embodiment are formed of black light-blocking material, also known as the black matrix, and a portion of the light-shielding portion 150 is covered by the color-filtering portion 140. In each non-opening area 102, on the orthographic projection of the substrate 110, the light-shielding portion 150 partially overlaps with the color-filtering portion 140.

In the present embodiment, the main part of each of the plurality of light-shielding portions 150 is disposed in each of the plurality of second grooves 125 respectively. Through the effect of each of the plurality of second grooves 125, the surface of the light-shielding portion 150 and the first inorganic layer 121 is made flatter. When forming each different color-filtering portions 140, the color-filtering portion 140 may be extended to the light-shielding portion 150, and the light-shielding portion 150 is configured to block the color-filtering portion 140 at that location. The surface of the light-shielding portion 150 away from the substrate 110 and the surface of the first inorganic layer 121 located in the plurality of opening areas away from the substrate 110 are roughly in the same plane.

In the present application, the surface of each film layer away from the substrate 110 is called as the upper surface, and the surface of each film layer close to the substrate 110 is called as the lower surface. In the following description, terms of "the upper surface" and "the lower surface" are used instead.

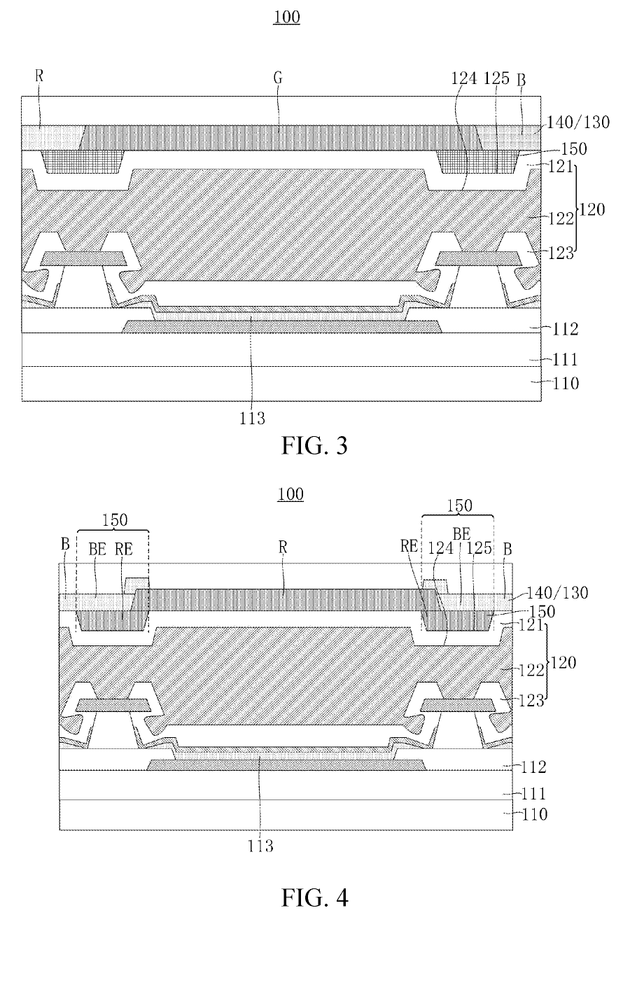

FIG. 3 is a schematic diagram of another display panel of a first embodiment of the present application. As shown in FIG. 3, a thickness of the light-shielding portion 150 may be less than or equal to a depth of each of the plurality of second grooves 125. Generally speaking, the thickness of the light-shielding portion 150 represented by the black matrix is generally much less than the thickness of the color-filtering portion 140. In the present embodiment, the depth of each of the plurality of second grooves 125 needs not to be too great, so that after the light-shielding portion 150 is filled, a film step difference between the upper surface of the light-shielding portion 150 and the upper surface of the first inorganic layer 121 located in the opening area does not become excessive, thereby allowing the underlying film more planar during formation of the color-filtering portion 140. By making the thickness of the light-shielding portion 150 slightly less than the depth of each of the plurality of second grooves 125, there is a film step difference between the upper surface of the first inorganic layer 121 located in the non-groove area after formation of the light-shielding portion 150, thereby forming a groove with a relatively shallow depth. Since this part is not configured for display even if the color-filtering portion 140 is formed. Therefore, forming a groove with a relatively shallow depth may accommodate excess color-filtering portion 140 material.

Specifically, the plurality of color-filtering portions 140 includes a plurality of red color-filtering portions R, a plurality of green color-filtering portions G and a plurality of blue color-filtering portions B. At each non-opening area 102, two adjacent color-filtering portions 140 may overlap or not overlap.

FIG. 4 is a schematic diagram of a display panel of a second embodiment of the present application. As shown in FIG. 4, the display panel 100 further includes a substrate 110, a pixel driving layer 111, a pixel defining layer 112, a plurality of light-emitting elements 113, an encapsulation layer 120 and a color-filtering layer 130. The pixel driving layer 111 is disposed on the substrate 110. The pixel defining layer 112 is disposed on the pixel driving layer 111 and located in the plurality of non-opening areas 102. The plurality of light-emitting elements 113 are arranged in an array on the pixel driving layer 111 and respectively located in the plurality of opening areas 101. The encapsulation layer 120 is disposed on the plurality of light-emitting elements 113, and the encapsulation layer 120 includes an organic encapsulation layer 122, the organic encapsulation layer 122 is provided with a first groove 124 corresponding to each of the plurality of non-opening areas 102. The color-filtering layer 130 is disposed on the encapsulation layer 120, and the color-filtering layer 130 includes a plurality of light-shielding portions 150 and a plurality of color-filtering portions 140, the plurality of color-filtering portions 140 are respectively arranged in the plurality of opening areas 101, and the plurality of light-shielding portions 150 are respectively arranged in a plurality of first grooves 124. In the present embodiment, each of the light-shielding portions 150 is no longer formed of a black light shielding material, but is formed by stacking color-filtering portions 140 of two colors.

Among the plurality of color-filtering portions 140, the plurality of color-filtering portions 140 of two colors are taken as an example for description. The plurality of color-filtering portions 140 includes a plurality of first color-filtering portions and a plurality of second color-filtering portions; the color of each of the plurality of first color-filtering portions is different from that of each of the plurality of second color-filtering portions; and in each of the plurality of non-opening areas, each of the plurality of first color-filtering portions is provided with an first color extension portion, each of the plurality of second color-filtering portion is provided with an second color extension portion, and the first color extension portion and the second color extension portion are stacked to form the light-shielding portion.

In the present embodiment, black shading material is no longer required to form the light-shielding portion 150. During the manufacturing process of the color-filtering portion 140, each light-shielding portions 150 is formed by stacking two color-filtering portions 140, so as to have light-proof properties. That is, the first color extension portion and the second color extension portion are stacked to form light-shielding portion 150. When light is emitted or incident, the first color extension portion filters the light and only passes the light of the first color. Since the second color extension portion only allows the light of the second color to pass through, the light of the first color that passes through the first color extension portion is unable to pass through the second color extension portion, thereby achieving a shading effect. By providing the plurality of second grooves 125, even after the first color extension portion and the second color extension portion are stacked, no "bull horn" defect is generated due to the stacking.

Specifically, the display panel further includes a plurality of overhang structures, which are disposed on the pixel defining layer; each of the plurality of overhang structures is configured to separate two adjacent light-emitting elements 113 respectively. The light-emitting element 113 generally includes a bottom electrode, a light-emitting functional layer and a top electrode. The plurality of overhang structures generally includes a conductive layer and an insulating layer. In each non-opening area, the width of the insulating layer is greater than the width of the conductive layer, so that when the light-emitting element 113 is evaporated on the entire surface, due to the shielding of the insulating layer, the light-emitting functional layer of the light-emitting element 113 is unable to be formed under the insulating layer, and is not connected to the light-emitting functional layer of the adjacent light-emitting element 113, nor is it connected to the redundant light-emitting functional layer on the plurality of overhang structure.

Specifically, each of the plurality of first color-filtering portions is a red color-filtering portion R, and each first color extension portion is a red extension portion RE; each of the plurality of second color-filtering portions is a blue color-filtering portion B, and each second color extension portion is a blue extension portion BE; the red extension portion RE is disposed below the blue extension portion BE within each of the plurality of non-opening areas 102.

In the present embodiment, the red color-filtering portion R, the red extension portion RE, the blue color-filtering portion B, and the blue extension portion BE are used as examples for explanation, and are not limited to the above two colors. Secondly, as for the stacking order of the red extension portion RE and the blue extension portion BE, the stacking order of the red extension portion RE and the blue extension portion BE may be determined according to the sequential process sequence of different colors. The main function of the light-shielding portion 150 in the present embodiment is to prevent ambient light from entering the interior of the display panel 100 to cause light reflection problems, and to isolate adjacent color-filtering portion 140 to prevent light crosstalk problems.

Specifically, the encapsulation layer 120 further includes a first inorganic encapsulation layer 121 disposed on the organic encapsulation layer 122, and the first inorganic encapsulation layer 121 covers the plurality of first grooves 124 to form the plurality of second grooves 125 respectively; the red extension portion RE and the blue extension portion BE are disposed in each of the plurality of second grooves 125 within each of the plurality of non-opening areas 102, and a depth of each of the plurality of second grooves 125 is equal to any one of a thickness of the blue extension portion BE and a thickness of the red extension portion RE.

The thickness of the organic encapsulation layer 122 in the first groove 124 region is less than the thickness of the organic encapsulation layer 122 in the region other than the first groove 124, and the depth of the first groove 124 generally needs to be greater than or equal to the thickness of the color-filtering layer 130 or the color-filtering portion 140. In general, the depth of the first groove 124 is equal to the depth of each of the plurality of second grooves 125. It should be understood that, when not considering the difference between the film thickness of the first inorganic layer 121 in the first groove 124 and the film thickness outside the first groove 124, it is generally believed that the depth of the first groove 124 is equal to the depth of each of the plurality of second grooves 125.

When the thickness of the organic encapsulation layer 122 is sufficient, the depth of the first groove 124 may be set slightly greater than the thickness of the color-filtering portion 140, so that the surface of the first color extension portion away from the substrate 110 is slightly lower than the surface of the first inorganic layer 121 located outside the first groove 124 after the first color extension portion is formed. The second color extension also sink slightly at the position of the first groove 124 when the second color extension portion is formed, so that the second color extension portion and each of the plurality of second color-filtering portion have better film flatness.

Specifically, under the orthographic projection of the substrate 110, the overlapping area of the red extension portion RE and the blue extension portion BE is greater than or equal to the area of the first groove 124. In the present embodiment, the overlapping area of the red extension portion RE and the blue extension portion BE is the shading area of the light-shielding portion 150, which should be greater than the area of the first groove 124 to achieve a better shading effect. The maximum area of the light-shielding portion 150 should not affect the light output of the opening area 101, so as to form the best shading effect in the non-opening area 102.

Specifically, the projection area of the first groove 124 on the substrate 110 should be less than or equal to the projection area of the non-opening area 102.

In one embodiment, the depth of each of the plurality of second grooves 125 is equal to the thickness of the blue extension portion BE or the thickness of the red extension portion RE. In the present embodiment, by setting the depth of each of the plurality of second grooves 125 to the thickness of the blue extension portion BE or the red extension portion RE, when forming the thickness of the light-shielding portion 150, the surface of the blue extension portion BE away from the substrate 110 and the surfaces of the blue color-filtering portion B and the red color-filtering portion R away from the substrate 110 are in the same plane.

In the present embodiment, by limiting the depth of each of the plurality of second grooves 125, the upper surface of the color-filtering layer 130 is made flatter, so that the flattening material is made thinner and the film thickness is reduced in the subsequent flattening process. By matching the depth of each of the plurality of second grooves 125 with the thickness of the color-filtering portion 140, the upper surface of the color-filtering portion 140 and the upper surface of the first inorganic layer 121 are in the same plane, the flatness of the color-filtering portion 140 is improved, the spectrum and brightness of each position are more uniform, the color purity and uniformity of the display are ensured, and the light scattering and reflection caused by the surface unevenness may be reduced.

Specifically, the plurality of color-filtering portions 140 of the display panel 100 includes a plurality of red color-filtering portions R, a plurality of blue color-filtering portions B and a plurality of green color-filtering portions G. Each of the plurality of red color-filtering portions R is provided with a red extension portion RE, each of the plurality of green color-filtering portions G is provided with a green extension portion GE, each of the plurality of blue color-filtering portions B is provided with a blue extension portion BE. And any two of the red extension portion RE, the green extension portion GE and the blue extension portion BE are stacked to form the light-shielding portion 150 in each of the plurality of non-opening areas.

In the present embodiment, the display panel 100 generally forms one pixel by one adjacent red color-filtering portion R, one blue color-filtering portion B and one green color-filtering portion G. The red color-filtering portion R may be configured as a red sub-pixel, the blue color-filtering portion B may be configured as a blue sub-pixel, and the green color-filtering portion G may be configured as a green sub-pixel. The red sub-pixel, the blue sub-pixel and the green sub-pixel form one pixel for display.

Specifically, the light-shielding portion 150 between the red sub-pixel and the blue sub-pixel may be formed by stacking the red extension portion RE and the blue extension portion BE. The light-shielding portion 150 between the red sub-pixel and the green sub-pixel and the light-shielding portion 150 between the blue sub-pixel and the green sub-pixel may be formed by stacking the red extension portion RE and the blue extension portion BE, or by stacking the red extension portion RE and an extension of the green color-filtering portion, or by stacking the blue extension portion BE and the extension of the green color-filtering portion.

For example, the plurality of light-shielding portions 150 in the display panel 100 are all formed by the red extension portion RE and the blue extension portion BE. When forming the red color-filtering portions R, it is necessary to retain the red extension portions RE of the plurality of non-opening areas 102, that is, the red extension portions RE in all second grooves 125 are retained. When forming the blue color-filtering portions B, the blue extension portions BE of all non-opening areas 102 are retained, that is, the blue extension portions BE in all second grooves 125. The light-shielding portion 150 is formed by using the red extension portion RE and the blue extension portion BE. By taking advantage of the blue color-filtering portions B and the red color-filtering portions R being at the two endpoints of the shorter and longer wavelengths respectively, a wavelength difference between the two is significant, no wavelength overlap portion exists, and better light shielding capability is provided.

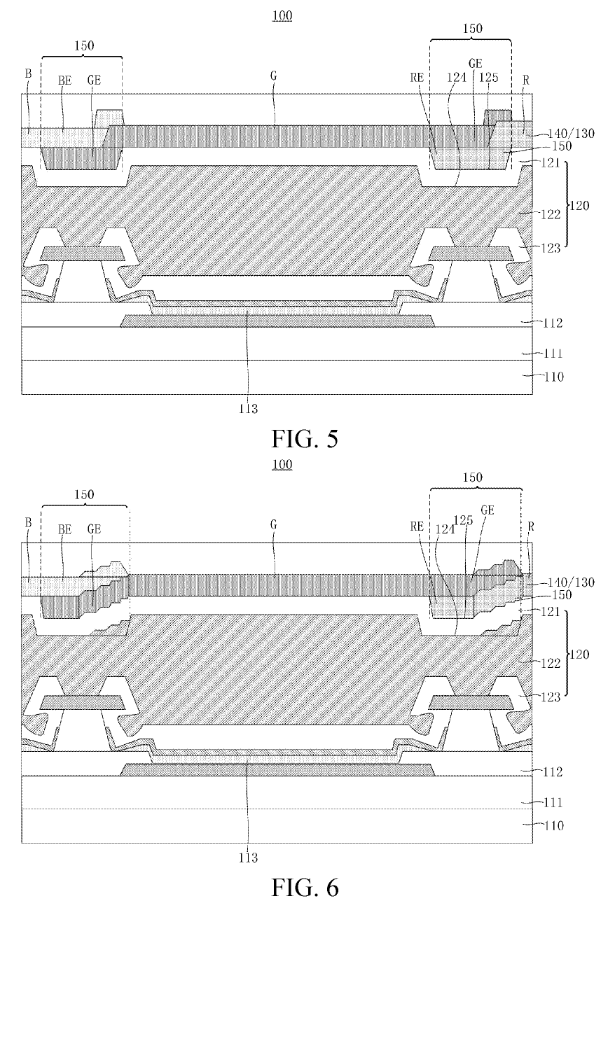

FIG. 5 is a schematic diagram of the second display panel of a second embodiment of the present application. As shown in FIG. 5, the light-shielding portion 150 between two different color sub-pixels is formed by using the color-filtering portions 140 corresponding to the two different color sub-pixels. For example, the light-shielding portion 150 between the red sub-pixel and the green sub-pixel is formed by stacking the red extension portion RE and a green extension portion GE. The light-shielding portion 150 between the green sub-pixel and the blue sub-pixel is formed by stacking the green extension portion GE and the blue extension portion BE. In the present embodiment, considering that the light-shielding portions 150 at different positions may be formed by stacking the extension portions of the color-filtering portions 140 on both sides, it is more convenient in terms of process.

Furthermore, considering the influence of the side wall of each of the plurality of second grooves 125, when the color-filtering portion 140 is formed on the entire surface, a film layer with a certain slope also be formed on the side wall of each of the plurality of second grooves 125, extending from the plurality of second grooves 125 to the non-second groove. Therefore, in the present embodiment, a side walls of the first groove 124 and the plurality of second grooves 125 may also be set as a multi-step stepped surface or a certain slope shape, so that the film layer thickness corresponding to the color extension parts of different colors in each of the plurality of non-opening areas is more uniform, and the change of the film layer height is relatively slow, and the steep side wall of each of the plurality of second grooves 125 does not cause a large change in the film layer in the transition area to the non-groove. However, the stepped surface or the side wall with a slope of 30 degrees to 70 degrees is only set on one side of each of the plurality of second grooves 125, for example, on the side of the color-filtering portion located below at the position of the light-shielding portion. FIG. 6 is a schematic diagram of another display panel of a second embodiment of the present application. As shown in FIG. 6, at the light shielding position where the blue extension portion BE and the green extension portion GE are located, the step surface is disposed on the side close to the green color-filtering portion G, and the green extension portion GE is arranged below the blue extension portion BE. At the light shielding position where the red extension portion RE and the green extension portion GE are located, the step surface is disposed on the side close to the red color-filtering portion R, and the green extension portion GE is arranged above the red extension portion RE.

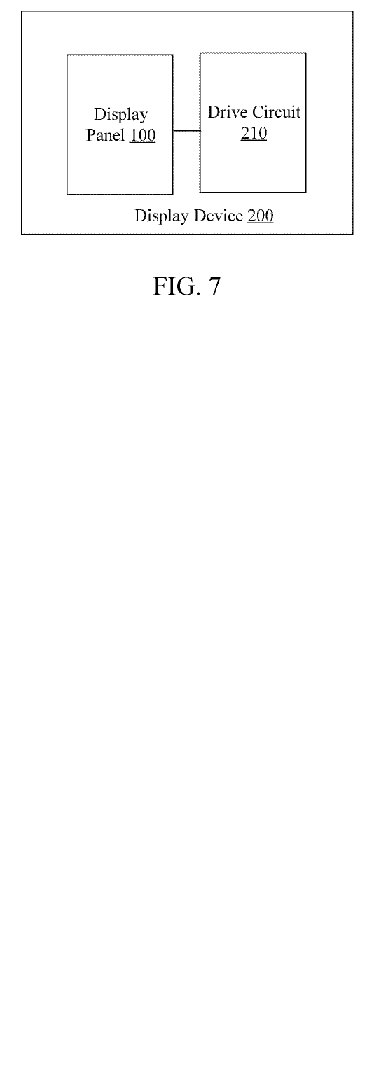

FIG. 7 is a schematic diagram of a display device according to the present application. As shown in FIG. 7, the present application further discloses a display device. The display device 200 includes a driving circuit 210 and any one of the display panels 100 in the above-mentioned embodiments 1 and 2. The driving circuit is configured to drive the display panel 100 to display.

It should be noted that the inventive concept of the present application may be formed into many embodiments, but limitations of the application document preclude exhaustive listing. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it should not be determined that the specific implementation of the present application is limited to these implementations. For those having ordinary skill in the art to which the present application pertains, several deductions or substitutions may be made without departing from the concept of the present application, and all these deductions or substitutions should be regarded as falling in the scope of protection of the present application.

What is claimed is:

1. A display panel, comprising a plurality of opening areas and a plurality of non-opening areas, wherein the display panel further comprises:
a substrate;
a pixel driving layer, disposed on the substrate;
a pixel defining layer, disposed on the pixel driving layer and located in the plurality of non-opening areas;
a plurality of light-emitting elements, arranged in an array on the pixel driving layer and respectively located in the plurality of opening areas;
an encapsulation layer, disposed on the plurality of light-emitting elements; and
a color-filtering layer, disposed on the encapsulation layer;
wherein the encapsulation layer comprises an organic encapsulation layer, the organic encapsulation layer is provided with a first groove corresponding to each of the plurality of non-opening areas, the color-filtering layer comprises a plurality of light-shielding portions and a plurality of color-filtering portions, the plurality of color-filtering portions are respectively arranged in the plurality of opening areas, and the plurality of light-shielding portions are respectively arranged in a plurality of first grooves.

2. The display panel according to claim 1, wherein the plurality of color-filtering portions comprises a plurality of first color-filtering portions and a plurality of second color-filtering portions; a color of each of the plurality of first color-filtering portions is different from that of each of the plurality of second color-filtering portions; and,
in each of the plurality of non-opening areas, each of the plurality of first color-filtering portions is provided with a first color extension portion, each of the plurality of second color-filtering portions is provided with a second color extension portion, and the first color extension portion and the second color extension portion are stacked to form the light-shielding portion.

3. The display panel according to claim 2, wherein each of the plurality of first color-filtering portions is a red filter portion, and each first color extension portion is a red extension portion; each of the plurality of second color-filtering portions is a blue filter portion, and each second color extension portion is a blue extension portion; and
the red extension portion is disposed below the blue extension portion within each of the plurality of non-opening areas.

4. The display panel according to claim 3, wherein, in each of the plurality of non-opening areas, in an orthographic projection on the substrate, an overlapping area of the red extension portion and the blue extension portion is greater than or equal to an area of the first groove.

5. The display panel according to claim 3, wherein a surface of the blue extension portion away from the substrate is in the same plane as surfaces of the blue color-filtering portion and the red color-filtering portion away from the substrate.

6. The display panel according to claim 3, wherein the encapsulation layer further comprises a first inorganic encapsulation layer disposed on the organic encapsulation layer, and the first inorganic encapsulation layer covers the plurality of first grooves to form a plurality of second grooves respectively; and,
within each of the plurality of non-opening areas, the red extension portion and the blue extension portion are disposed in each of the plurality of second grooves, and a depth of each of the plurality of second grooves is equal to any one of a thickness of the blue extension portion and a thickness of the red extension portion.

7. The display panel according to claim 3, wherein the display panel further comprises a plurality of overhang structures disposed on the pixel defining layer; each of the plurality of overhang structures is configured to separate two adjacent light-emitting elements respectively.

8. The display panel according to claim 2, wherein the plurality of color-filtering portions comprises a plurality of red color-filtering portions, a plurality of blue color-filtering portions and a plurality of green color-filtering portions;
each of the plurality of red color-filtering portions is provided with a red extension portion, each of the plurality of green color-filtering portions is provided with a green extension portion, each of the plurality of blue color-filtering portions is provided with a blue extension portion; and,
any two of the red extension portion, the green extension portion and the blue extension portion are stacked to form the light-shielding portion in each of the plurality of non-opening areas.

9. The display panel according to claim 1, wherein each of the plurality of light-shielding portions is formed of a black light-shielding material; at least one of the color-filtering portions is disposed to cover the light-shielding portion in each of the non-opening areas, and each of the plurality of light-shielding portion partially overlaps each of the plurality of color-filtering portion in the orthographic projection on the substrate.

10. The display panel according to claim 8, wherein the encapsulation layer further comprises a first inorganic encapsulation layer disposed on the organic encapsulation layer, and the first inorganic encapsulation layer covers the plurality of first grooves to form a plurality of second grooves respectively,
wherein a thickness of the light-shielding portion is less than or equal to a depth of each of the plurality of second grooves.

11. The display panel according to claim 9, wherein the light-shielding portion is covered with at least one color-filtering portion in each of the plurality of non-opening areas.

12. The display panel according to claim 6, wherein a side wall of the first groove has a multi-stepped stair-like surface; and a side wall of each of the plurality of second grooves has a multi-stepped stair-like surface.

13. A display device, comprising a display panel and a driving circuit configured to drive the display panel to display; wherein the display panel comprises a plurality of opening areas and a plurality of non-opening areas, and the display panel further comprises:
a substrate;
a pixel driving layer, disposed on the substrate;
a pixel defining layer, disposed on the pixel driving layer and located in the plurality of non-opening areas;
a plurality of light-emitting elements, arranged in an array on the pixel driving layer and respectively located in the plurality of opening areas;
an encapsulation layer, disposed on the plurality of light-emitting elements; and
a color-filtering layer, disposed on the encapsulation layer;
wherein the encapsulation layer comprises an organic encapsulation layer, the organic encapsulation layer is provided with a first groove corresponding to each of the plurality of non-opening areas;
the color-filtering layer comprises a plurality of light-shielding portions and a plurality of color-filtering portions, the plurality of color-filtering portions are respectively arranged in the plurality of opening areas, and the plurality of light-shielding portions are respectively arranged in a plurality of first grooves.

14. The display device according to claim 13, wherein the plurality of color-filtering portions comprises a plurality of first color-filtering portions and a plurality of second color-filtering portions; a color of each of the first color-filtering portions is different from that of each of the plurality of second color-filtering portions; and,
in each of the plurality of non-opening areas, each of the plurality of first color-filtering portion is provided with a first color extension portion, each of the plurality of second color-filtering portions is provided with a second color extension portion, and the first color extension portion and the second color extension portion are stacked to form the light-shielding portion.

15. The display device according to claim 14, wherein each of the plurality of first color-filtering portions is a red color-filtering portion, and each first color extension portion is a red extension portion; each of the plurality of second color-filtering portions is a blue color-filtering portion, and each second color extension portion is a blue extension portion;
the red extension portion is disposed below the blue extension portion within each of the plurality of non-opening areas.

16. The display device according to claim 15, wherein in each of the plurality of non-opening areas, in an orthographic projection on the substrate, an overlapping area of the red extension portion and the blue extension portion is greater than or equal to an area of the first grooves.

17. The display device according to claim 15, wherein a surface of the blue extension portion away from the substrate is in the same plane as surfaces of the blue color-filtering portion and the red color-filtering portion away from the substrate.

18. The display device according to claim 15, wherein the encapsulation layer further comprises a first inorganic encapsulation layer, disposed on the organic encapsulation layer, and the first inorganic encapsulation layer covers the plurality of first grooves to form a plurality of second grooves respectively; and,
within each of the plurality of non-opening areas, the red extension portion and the blue extension portion are disposed in the plurality of second grooves, and a depth of each of the plurality of second grooves is equal to any one of a thickness of the blue extension portion and a thickness of the red extension portion.

19. The display device according to claim 15, wherein the display panel further comprises a plurality of overhang structures, disposed on the pixel defining layer; each of the plurality of overhang structures is configured to separate two adjacent light-emitting elements respectively.

20. The display device according to claim 14, wherein the plurality of color-filtering portions comprises a plurality of red color-filtering portions, a plurality of blue color-filtering portions and a plurality of green color-filtering portions,
each of the plurality of red color-filtering portions is provided with a red extension portion, each of the plurality of green color-filtering portions is provided with a green extension portion, each of the plurality of blue color-filtering portions is provided with a blue extension portion; and
any two of the red extension portion, the green extension portion and the blue extension portion are stacked to form the light-shielding portion in each of the plurality of non-opening areas.
